(19) United States
(12) Patent Application Publication
(10) Pub. No.: US 2024/0193755 A1
(43) Pub. Date: Jun. 13, 2024

(54) PATTERN DEFECT INSPECTION DEVICE AND PATTERN DEFECT INSPECTION METHOD

(71) Applicant: Samsung Electronics Co., Ltd., Suwon-si (KR)

(72) Inventors: Jungkee CHOI, Suwon-si (KR); Noyoung CHUNG, Suwon-si (KR)

(73) Assignee: Samsung Electronics Co., Ltd., Suwon-si (KR)

(21) Appl. No.: 18/526,242

(22) Filed: Dec. 1, 2023

(30) Foreign Application Priority Data
Dec. 7, 2022 (KR) 10-2022-0170050

(51) Int. Cl. G06T 7/00; G06T 7/11

(52) U.S. Cl. CPC G06T 7/0006; G06T 7/11; G01N 2223/401; G01N 2223/611; G06T 2207/10061; G06T 2207/20021; G06T 2207/30148

(57) ABSTRACT

A pattern defect inspection device includes an inspection apparatus inspecting a pattern on a substrate, a database storing a pattern layout including a plurality of defect patterns from the inspection apparatus, a preset field of view (FOV) size, and a target measurement number, and a processor setting a plurality of inspection regions of the inspection apparatus based on the pattern layout, wherein the processor includes a defect search unit searching for a region defect pattern existing in any one of a plurality of inspection regions in the pattern layout, an inspection region aligning unit arranging the plurality of inspection regions based on the region defect pattern, an overlapping region removal unit removing an overlapping region from the plurality of inspection regions, and an inspection region selecting unit selecting an inspection region other than the overlapping region, among the plurality of inspection regions, as a final inspection region.

### CROSS-REFERENCE TO RELATED APPLICATION

This application is based on and claims priority under 35 U.S.C. § 119 to Korean Patent Application No. 10-2022-0170050, filed on Dec. 7, 2022, in the Korean Intellectual Property Office, the disclosure of which is incorporated by reference herein in its entirety.

### BACKGROUND

The inventive concepts relate to a pattern defect inspection device and a pattern defect inspection method.

In order to prevent electrical defects of semiconductor devices due to pattern defects, pattern defect inspection is performed. However, as the semiconductor process has been miniaturized and complicated, the size of pattern defects that may occur during a semiconductor manufacturing process has also been reduced. The level of inspection requirements for detecting such fine pattern defects has increased, and various attempts have been made to quickly detect pattern defects within limited conditions.

### SUMMARY

The inventive concepts provide a pattern defect inspection device and a pattern defect inspection method capable of quickly and accurately detecting pattern defects.

In addition, the problems to be solved by the inventive concepts is not limited to the above-mentioned problems, and other problems may be clearly understood by those skilled in the art from the description below.

According to an aspect of the inventive concepts, there is provided a pattern defect inspection device including an inspection apparatus configured to inspect a pattern on a substrate; a database storing a pattern layout including a plurality of defect patterns from the inspection apparatus, a field of view (FOV) size, and a target measurement number; and a processor configured to set a plurality of inspection regions of the inspection apparatus based on the pattern layout, search for a region defect pattern existing in at least one of the plurality of inspection regions in the pattern layout using a binary search, arrange the plurality of inspection regions based on the region defect pattern, remove at least one overlapping region from the plurality of inspection regions based on the FOV size, and select an inspection region, other than the at least one overlapping region, from among the plurality of inspection regions, as a final inspection region.

According to another aspect of the inventive concepts, there is provided a pattern defect inspection device including an inspection apparatus configured to inspect a pattern on a substrate; a database storing a pattern layout including a plurality of defect patterns from the inspection apparatus, a field of view (FOV) size, a target inspection time, and a target measurement number; and a processor configured to set a plurality of inspection regions of the inspection apparatus based on the pattern layout, wherein the processor is configured to measure a number of defect patterns in each of the plurality of inspection regions based on the FOV size, determine whether the plurality of inspection regions overlap by setting one of the plurality of inspection regions as a reference region, the reference region set based on an order in which the number of defect patterns increases, remove an overlapping region overlapping the reference region, select an inspection region from among the plurality of inspection regions, other than the overlapping region which is removed, as a final inspection region, and correct the FOV size and the target measurement number and reselect the plurality of inspection regions when an expected inspection time for the final inspection region exceeds the target inspection time.

According to another aspect of the inventive concepts, there is provided a pattern defect inspection method includes searching for region defect patterns existing in at least one of a plurality of inspection regions in a pattern layout using a binary search, the patter layout including a plurality of defect patterns; arranging the plurality of inspection regions in a descending order based on a number of the region defect patterns in the plurality of inspection regions; removing at least one overlapping region, among the plurality of inspection regions, based on a field of view (FOV) size; selecting an inspection region, other than the overlapping region, from among the plurality of inspection regions, as a final inspection region; and inspecting a pattern on a substrate corresponding to the final inspection region.

### BRIEF DESCRIPTION OF THE DRAWINGS

Embodiments will be more clearly understood from the following detailed description taken in conjunction with the accompanying drawings in which:

FIG. 1 is a diagram schematically illustrating a pattern defect inspection device used in a pattern defect inspection method according to at least one example embodiment of the inventive concepts;

FIG. 2 is a conceptual diagram illustrating a pattern defect inspection device according to at least one example embodiment of the inventive concepts;

FIG. 3 is a schematic plan view of a semiconductor substrate of FIG. 1;

FIG. 4 is a plan view illustrating a defect pattern present in a semiconductor substrate of FIG. 1;

FIG. 5 is a plan view illustrating a pattern layout according to at least one example embodiment of the inventive concepts;

FIG. 6 is a flowchart illustrating a pattern defect inspection method according to at least one example embodiment of the inventive concepts;

FIGS. 7 to 9 are diagrams illustrating a pattern defect inspection method according to at least one example embodiment of the inventive concepts; and

FIG. 10 is a flowchart illustrating a method of manufacturing a semiconductor device, according to according to at least one example embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

When the terms “about” or “substantially” are used in this specification in connection with a numerical value and/or geometric terms, it is intended that the associated numerical value includes a manufacturing tolerance (e.g., ±10%) around the stated value and/or term. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Functional terms such as those including “unit”, and/or “ . . . er/or” described in the specification represent units that process at least one function or operation, and may be implemented as processing circuitry such as hardware, software, or a combination of hardware and software, unless expressly indicated otherwise. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

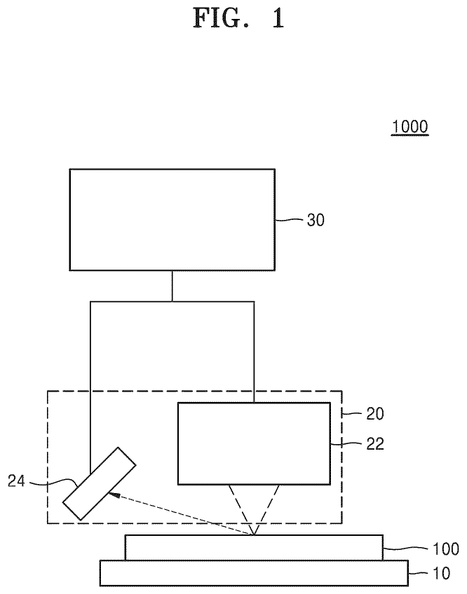

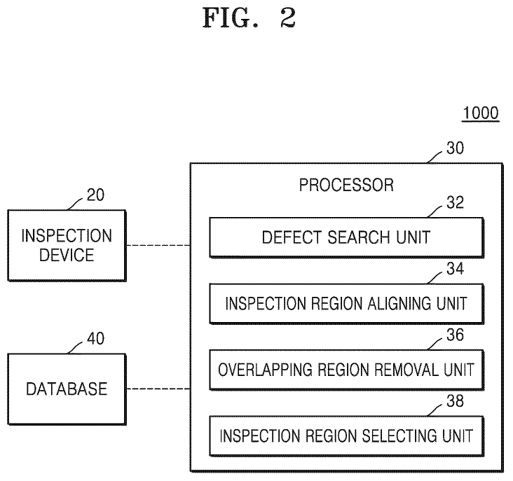

FIG. 1 is a diagram schematically illustrating a pattern defect inspection device 1000 used in a pattern defect inspection method according to at least one example embodiment of the inventive concepts. FIG. 2 is a conceptual diagram illustrating the pattern defect inspection device 1000 according to at least one example embodiment of the inventive concepts.

Referring to FIGS. 1 and 2, the pattern defect inspection device 1000 may include a stage 10, an inspection apparatus 20, and a processor 30. The stage may be configured to seat a semiconductor substrate 100. The inspection apparatus 20 may be connected to the processor 30.

The inspection apparatus 20 may include an electron supply unit 22 and an electron detection unit 24. For example, the inspection apparatus may be and/or include an electron microscope and/or electron microscopy device.

The inspection apparatus 20 may inspect patterns formed on the semiconductor substrate 100. The inspection apparatus 20 may scan electron beams to the semiconductor substrate 100 through the electron supply unit 22. In addition, the inspection apparatus 20 may detect secondary electrons emitted from the semiconductor substrate 100 through the electron detection unit 24.

In some embodiments, the inspection apparatus 20 may be any one of a scanning electron microscope (SEM), a transmission electron microscope (TEM), an electron beam inspection apparatus, and/or the like.

The inspection apparatus 20 may generate data on the patterns (e.g., image data on the patterns) by scanning the intensity of the secondary electrons emitted from the patterns on the semiconductor substrate 100.

The processor 30 may be connected to the electron supply unit 22 and the electron detection unit 24 of the inspection apparatus 20. The processor 30 may provide data to the inspection apparatus 20 or store and process data generated by the inspection apparatus 20.

For example, the processor 30 may control at least one other component (e.g., the electron supply unit 22 or the electron detection unit 24) of the inspection apparatus 20 connected to the processor 30 and perform various data processing or calculation by executing software. According to at least one example embodiment, as at least part of data processing or calculation, the processor 30 may store data received from other components (e.g., the electron supply unit 22 or the electron detection unit 24) in a volatile memory, process a command or data stored in the volatile memory, and store resultant data in a non-volatile memory.

According to at least one example embodiment, the processor 30 may include a main processor (e.g., a central processing unit (CPU) and/or an application processor) and/or an auxiliary processor (e.g., a graphics processing unit (GPU) and/or a neural processing unit (NPU), an image signal processor, a sensor hub processor, or a communication processor) operable independently or together with the main processor.

For example, when the inspection apparatus 20 includes a main processor and an auxiliary processor, the auxiliary processor may use less power than the main processor or may be set to be specialized for a designated function. In at least some embodiments, the auxiliary processor may be implemented separately from or as part of the main processor 121.

The auxiliary processor may control at least some of functions or states related to at least one (e.g., the electron supply unit 22 or the electron detection unit 24) of the components of the inspection apparatus 20, for example, on behalf of the main processor while the main processor is in an inactive (e.g., sleep) state, or together with the main processor while the main processor is in an active (e.g., application executed) state.

According to at least one example embodiment, the auxiliary processor (e.g., an image signal processor or a communication processor) may be implemented as part of other functionally related components (e.g., a communication module). According to at least one example embodiment, the auxiliary processor (e.g., an NPU) may include a hardware structure specialized for processing an artificial intelligence (AI) model. The AI models may be created through machine learning. Such learning may be performed, for example, in the inspection apparatus 20 itself in which the AI model is performed, or may be performed through a separate server.

The learning algorithm may include, for example, supervised learning, unsupervised learning, semi-supervised learning, or reinforcement learning but is not limited thereto. The AI model may include a plurality of artificial neural network layers. Artificial neural networks may include deep neural networks (DNNs), convolutional neural networks (CNNs), recurrent neural networks (RNNs), restricted Boltzmann machines (RBMs), deep belief networks (DBNs), bidirectional recurrent deep neural networks (BRDNNs), deep Q-networks or a combination of two or more thereof but are not limited thereto. The AI model may include, additionally or alternatively, software structures in addition to hardware structures.

Also, the processor 30 may set a plurality of inspection regions of the inspection apparatus 20 based on a pattern layout. The processor 30 may include a defect search unit 32, an inspection region aligning unit 34, an overlapping region removal unit 36, and an inspection region selecting unit 38. The defect search unit 32 may search for a region defect pattern existing in any one inspection region among a plurality of inspection regions in the pattern layout on the semiconductor substrate 100 by using a binary search method. The inspection region aligning unit 34 may align the inspection regions one another based on the region defect pattern. The overlapping region removal unit 36 may remove overlapping regions based on a size of a preset field of view (FOV) among the inspection regions. The inspection region selecting unit 38 may remove an overlapping region based on the size of the preset FOV among the inspection regions.

A database (DB) 40 may have a general data structure implemented in a storage space (a hard disk or memory) of a computer system using a database management program (DBMS) The DB 40 may have a data storage form in which data may be freely searched for (extracted), deleted, edited, added, and the like. The DB 40 may be implemented using, for example, a relational database management system (RDBMS), such as Oracle, Informix, Sybase, and DB2, an object-oriented database management system (OODBMS), such as Gemston, Orion, and O2, or an XML-only DB (XML native DB), such as Excelon, Tamino, Sekaiju, and/or the like, and may have appropriate fields or elements to achieve a function thereof.

Also, the DB 40 may receive data from the inspection apparatus 20 and store the received data. The DB 40 may store the pattern layout including a plurality of defect patterns from the inspection apparatus 20, the size of the preset FOV, a target measurement time, and a target measurement number.

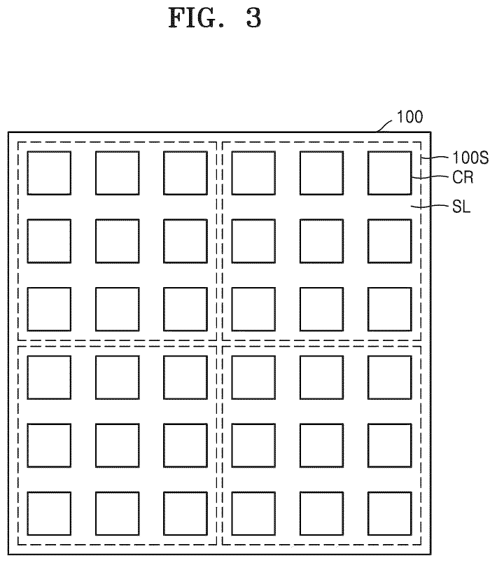

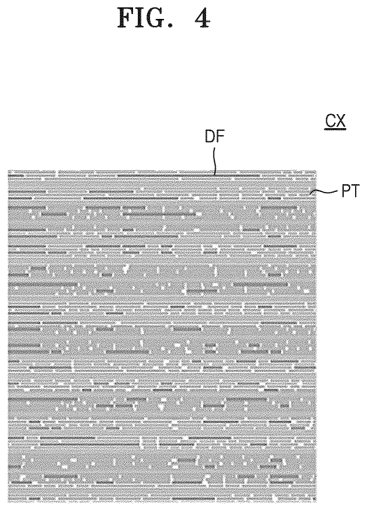

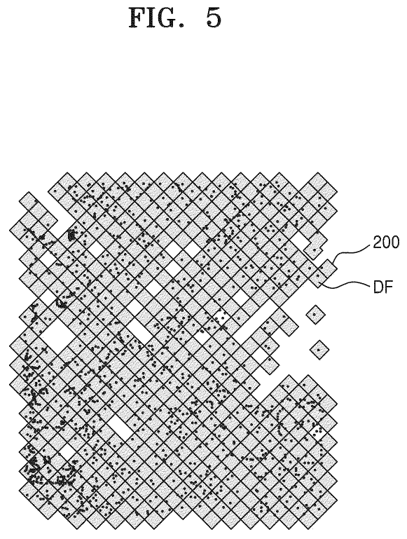

FIG. 3 is a schematic plan view of the semiconductor substrate 100 of FIG. 1. FIG. 4 is a plan view illustrating a defect pattern present in the semiconductor substrate 100 of FIG. 1. FIG. 5 is a plan view illustrating a pattern layout according to at least one example embodiment of the inventive concepts.

Referring to FIG. 3, the semiconductor substrate 100 may include a plurality of chip regions CR and a scribe line SL between the chip regions CR.

Semiconductor devices (e.g., transistors, capacitors, resistors, and inductors) constituting a semiconductor integrated circuit (IC) may be formed on the chip regions CR. Among the chip regions CR, chip regions CR adjacent to each other may be defined as one group (e.g., a shot 100S). The adjacent chip regions CR in the shot 100S may be simultaneously exposed when a photolithography process for forming semiconductor devices is performed. The number of adjacent chip regions CR defined as one shot 110s may be, for example, nine (9), but the inventive concepts are not limited thereto.

Referring to FIGS. 3 to 5, patterns PT constituting semiconductor devices on the semiconductor substrate 100 may include a defect pattern DF. The inspection apparatus (e.g., 20 in FIG. 1) may receive a plurality of inspection regions 200 from the processor 30 and inspect the defect pattern DF existing in the inspection regions 200 regarding the patterns PT.

The semiconductor substrate 100 may include patterns formed on the chip regions CR and constituting the semiconductor devices. As the degree of integration of the semiconductor devices increases, the number of patterns formed on the semiconductor substrate 100 may increase. Accordingly, the number of patterns to be inspected (or inspection target patterns) among the patterns may also increase in order to minimize and/or prevent defects in the manufactured semiconductor devices.

Hereinafter, a defect pattern inspection method for easily inspecting the inspection target patterns using the pattern defect inspection device 1000 of FIG. 1 is described.

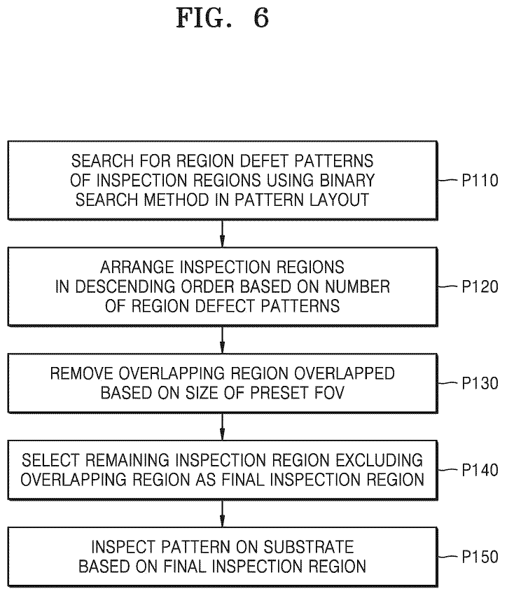

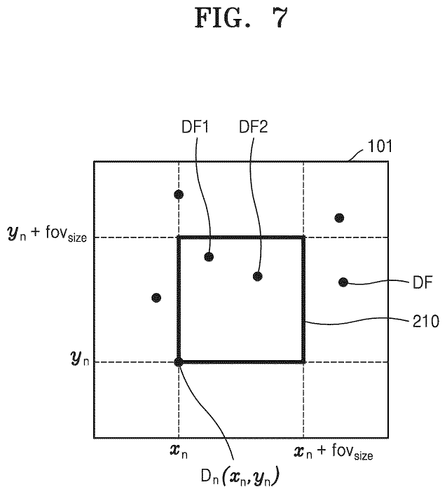

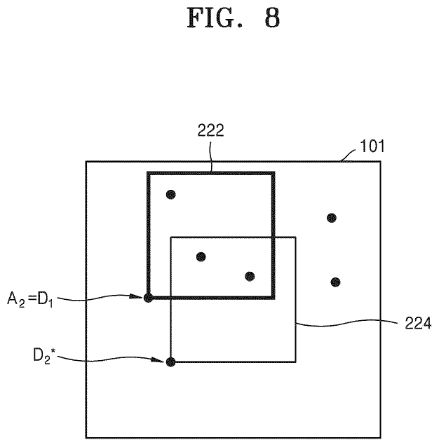

FIG. 6 is a flowchart illustrating a pattern defect inspection method according to at least one example embodiment of the inventive concepts. FIGS. 7 to 9 are diagrams illustrating a pattern defect inspection method according to at least one example embodiment of the inventive concepts. Hereinafter, a description is given with reference to FIG. 2, and the description already given above with respect to FIG. 2 is briefly given or omitted.

In FIGS. 7 to 9, the horizontal axis represents the X axis and the vertical axis represents the Y axis. Hereinafter, an X-axis direction is referred to as a first direction, and a Y-axis direction is referred to as a second direction. The second direction may be perpendicular to the first direction.

Referring to FIGS. 2, 6, and 7, first, a region defect pattern of a plurality of inspection regions may be searched for in a pattern layout using a binary search method (P110). According to some embodiments, a first inspection region 210, among the inspection regions, may be set based on a first point (xₙ,yₙ). Here, referring to a partial pattern region 101, a point corresponding to any one defect pattern Dₙ, among a plurality of defect patterns DF, may be set as the first point (xₙ,yₙ). For example, one of a plurality of corner points of the first inspection region 210 may coincide with the first point (xₙ,yₙ).

In order to obtain the number of defect patterns included in the first inspection region 210 based on the first point (xₙ,yₙ), defect patterns in the first distance (e.g., FOV size (fov_{size}) in the first direction) satisfying Equation 1 below may be searched for. The FOV size may include a first horizontal directional length that is an FOV size in the first direction and a second vertical directional length that is an FOV size in the second direction perpendicular to the first direction. The first horizontal directional length may be equal to the second vertical directional length. Each of the first horizontal directional length and the second vertical directional length may be referred to as the FOV size or a size of the FOV.

xᵢ≤xⱼ≤xᵢ+fov_{size},xᵢ=xₙ [Equation 1]

Here, xⱼ represents an X-axis coordinate of the defect pattern. In some embodiments, the defect search unit 32 may search for the defect pattern DF having X-Y axis coordinates satisfying Equation 1 above using a binary search. Through this, first defect patterns DF1, DF2, and DF3 existing within the FOV size in the first direction may be searched for based on the first point (xₙ,yₙ). Here, the first defect patterns DF1, DF2, and DF3 may include a (1-1)-th defect pattern DF1, a (1-2)-th defect pattern DF2, a (1-3)-th defect pattern DF3, etc.

Next, the found first defect patterns DF1, DF2, and DF3 may be arranged in descending order based on a Y-axis coordinate value. For example, based on the Y-axis coordinate value, the (1-2)-th defect pattern DF2, the (1-1)-th defect pattern DF1, and the (1-3)-th defect pattern DF3 may be arranged in this order. After the first defect patterns DF1, DF2, and DF3 are arranged, defect patterns within a second distance in a second direction (e.g., FOV size (fov_{size}) in the second direction) satisfying Equation 2 below may be searched for.

yᵢ≤yⱼ≤yᵢ+fov_{size},yᵢ=yₙ [Equation 2]

Here, yj represents the Y-axis coordinate of the defect pattern. In some embodiments, the defect search unit 32 may search for the defect pattern DF having X-Y coordinates satisfying Equation 2 among the first defect patterns DF1, DF2, and DF3 using a binary search. Through this, the second defect patterns DF1 and DF2 existing within the size of the FOV in the second direction based on the first point (xₙ, yₙ) may be searched for. Here, the second defect patterns DF1 and DF2 may include the (1-1)-th defect pattern DF1 and the (1-2)-th defect pattern DF2. The second defect patterns DF1 and DF2 may refer to all defect patterns existing in the first inspection region 210, and the second defect patterns DF1 and DF2 may be first region defect patterns. In this manner, the defect patterns existing in the first inspection region 210 having the first point (xₙ,yₙ) as a reference point may be searched for.

The defect search unit 32 of the processor 30 may set an inspection region like the first inspection region 210 using each of the defect patterns in the pattern layout as a reference point, and search for a defect pattern existing in each inspection region. In some embodiments, the defect search unit 32 of the processor 30 may search for a first region defect pattern in the first inspection region 210 and a second region defect pattern in a second inspection region (not shown). The defect search unit 32 of the processor 30 may repeatedly perform operation P110 for all of the defect patterns existing in the pattern layout.

After the region defect patterns are searched for, the inspection region aligning unit 34 may arrange the plurality of inspection regions in descending order based on the number of region defect patterns (P120). In some embodiments, when the first inspection region 210 has two defect patterns, the second inspection region has three defect patterns, and the third inspection region has one defect pattern, the second inspection region, the first inspection region 210, and the third inspection region may be arranged in this order.

Referring to FIGS. 2, 6, and 8, after the inspection regions are arranged, overlapping regions may be removed based on the preset FOV size (P130).

First, the overlapping region removal unit 36 of the processor 30 may select a reference region for determining whether the inspection regions overlap in the order in which the inspection regions are arranged by the inspection region aligning unit 34. For example, referring to a first inspection region 222 and a second inspection region 224, among the inspection regions, the first inspection region 222 has three region defect patterns, and the second inspection region 224 has two region defect patterns. In these cases, it is assumed that the first inspection region 222 and the second inspection region 224 are already arranged in this order by the inspection region aligning unit 34.

Here, because the first inspection region 222 is a higher priority inspection region than the second inspection region 224, the overlapping region removal unit 36 may first select the first inspection region 222 as a reference region. Determining of overlapping by the overlapping region removal unit 36 may be performed based on a distance between a first reference point D1 of the first inspection region 222 and a second reference point D2 of the second inspection region 224. Here, the second inspection region 224 may be a one determination target region, among the inspection regions. For example, when the first reference point D1 has coordinates of (xₛ,yₛ) and the second reference point D2 has coordinates of (xₐ,yₐ), whether the first inspection region 222 and the second inspection region 224 overlap each other may be determined using Equation 3 below.

|xₛ−xₐ|≥fov_{size} OR |yₛ−yₐ|≥fov_{size} [Equation 3]

In some embodiments, when an absolute value of a difference between the X coordinate value of the first reference point D1 and the X coordinate value of the second reference point D2 is greater than or equal to the size of the FOV or when an absolute value of a difference between the Y coordinate value of the first reference point D1 and the Y coordinate value of the second reference point D2 is greater than or equal to the size of the FOV, it may be determined that the first inspection region 222 and the second inspection region 224 do not overlap each other. Here, the absolute value of the difference between the X coordinate value of the first reference point D1 and the X coordinate value of the second reference point D2 may correspond to a horizontal distance between the first reference point D1 and the second reference point D2 in the first direction. In addition, the absolute value of the difference between the Y coordinate value of the first reference point D1 and the Y coordinate value of the second reference point D2 may correspond to a vertical distance between the first reference point D1 and the second reference point D2 in the second direction.

In some embodiments, when the absolute value of the difference between the X coordinate value of the first reference point D1 and the X coordinate value of the second reference point D2 is less than the size of the FOV and the absolute value of the difference between the Y coordinate value of the first reference point D1 and the Y coordinate value of the second reference point D2 is less than the size of the FOV, the first inspection region 222 and the second inspection region 224 may be determined to overlap each other.

When the first inspection region 222 and the second inspection region 224 are determined to overlap each other, a second inspection region 224, different from the first inspection region 222 corresponding to the reference region, may be excluded from the inspection regions. For example, an inspection region having more region defect patterns may be set as a candidate group of a final inspection region, and an overlapping region may be excluded.

Because the first inspection region 222 is a reference region, all overlapping regions overlapping the first inspection region 222 may be removed from the region to be inspected, and then an inspection region arranged next to the first inspection region 222 may be selected as a reference region. A method of removing an overlapping region with respect to the reference region may be performed in the same manner as a method of removing an overlapping region with respect to the first inspection region 222. P130 may be repeatedly performed until the number of inspection regions excluding the overlapping region from the inspection regions reaches a preset target measurement number.

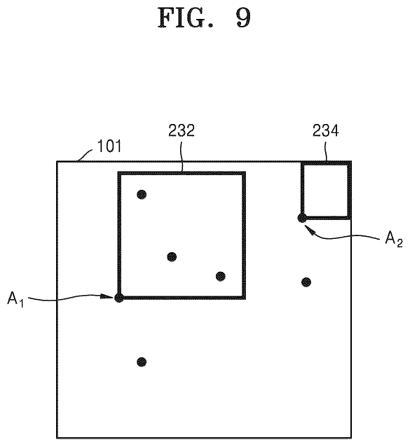

Referring to FIGS. 2, 6, and 9, after the overlapping region is removed, a remaining inspection region excluding the overlapping region may be selected as a final inspection region by the inspection region selecting unit 38 (P140). The remaining inspection region other than the overlapping region may be referred to as a non-overlapping inspection region. The final inspection region may include the same number of inspection regions as the preset target measurement number. As shown in FIG. 9, the final inspection regions do not overlap each other, and an inspection region including a maximum number of defect patterns within a limited number of inspection regions may be selected as the final inspection region. The processor 30 may set the final inspection region to a plurality of inspection regions. In addition, the processor 30 may control the inspection apparatus 20 to inspect the pattern on the substrate based on the final inspection region.

In operation P140, the inspection region from which the overlapping region is removed among the inspection regions is selected as a final inspection region, and an expected inspection time may be determined. If the expected inspection time for the final inspection region exceeds a preset (and/or otherwise determined) target inspection time, the size of the FOV and the target measurement number may be corrected, and the inspection regions may be reselected based on the corrected size of the FOV and the target measurement number. For example, un at least one embodiment, the size of the FOV may be reduced to reduce the inspection time. The reselection method may refer to re-performing P110 to P140 based on the corrected FOV size and target measurement number.

In some embodiments, the processor 30 may transfer the final inspection region to the inspection apparatus 20 when the inspection time for the final inspection region is less than or equal to the target inspection time previously set in the DB 40.

After selecting the final inspection region, a pattern on the substrate may be inspected based on the final inspection region (P150). Because the region with many defects is mainly selected as the final inspection region based on the defect of the existing pattern, the defect pattern that may occur in the pattern on the substrate may be detected quickly and efficiently.

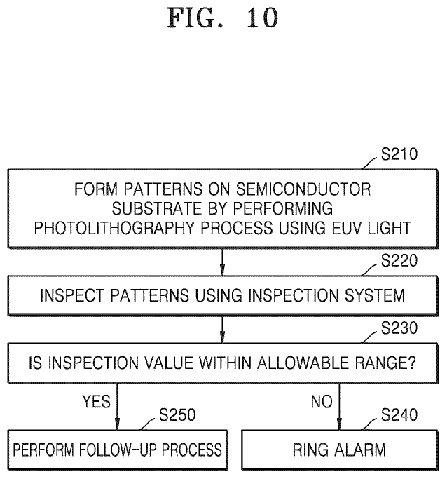

FIG. 10 is a flowchart illustrating a method of manufacturing a semiconductor device, according to at least one example embodiment. Descriptions are given with reference to FIGS. 1 to 3 also, and the description already given above with respect to FIGS. 1 to 3 is briefly given or omitted.

Referring to FIG. 10, patterns may be formed on the semiconductor substrate 100 described above with reference to FIG. 3 by performing a photolithography process using, e.g., extreme ultraviolet (EUV) light (S210). The patterns may be formed on the plurality of chip regions CR of the semiconductor substrate 100, and the chip regions CR adjacent to each other in one shot 100S may be simultaneously exposed by the photolithography process. The photolithography process may transfer the pattern layout described above with reference to FIG. 3 onto the chip regions CR of the semiconductor substrate 100.

EUV light may refer to ultraviolet rays having a wavelength of about 4 nm and about 124 nm, specifically, a wavelength of about 4 nm and about 20 nm, and more specifically, a wavelength of about 13.5 nm. EUV light may refer to light having energy of about 6.21 eV to about 124 eV, specifically, about 90 eV to about 95 eV. The photolithography process using EUV light may include an exposure and development process using EUV light irradiated onto a photoresist layer on the semiconductor substrate 100. For example, the photoresist layer may be an organic photoresist including an organic polymer, such as polyhydroxystyrene. In at least some embodiments, the organic photoresist may further include a photosensitive compound that reacts to EUV light. The organic photoresist may include a material having high EUV absorption, for example, an organometallic material, an iodine-containing material, a fluorine-containing material, and/or the like. As another example, the photoresist layer may be an inorganic photoresist including an inorganic material, such as tin oxide.

The photoresist layer may be formed to have a relatively small thickness. Photoresist patterns may be formed on the semiconductor substrate 100 by developing the photoresist layer exposed to EUV light. For example, in a plan view, the photoresist patterns may have a line shape extending in one direction, an island shape, a zigzag shape, a honeycomb shape, and/or a circular shape, but are not limited thereto. The photoresist patterns may have a planar shape and size corresponding to design images of the patterns of the pattern layout of FIG. 3.

Using the photoresist patterns as an etch mask, one or more mask layers stacked there below may be patterned to form mask patterns. The patterns may be formed on the semiconductor substrate 100 by patterning a target layer using the mask patterns as an etching mask.

As a comparative example of the inventive concepts, a multi-patterning technique (MPT) using two or more photo masks may be used to form the patterns having a fine pitch on the semiconductor substrate 100. In contrast, in the case of performing the EUV lithography process according to at least one example embodiment, the patterns having a fine pitch may be formed even with a single photo mask. For example, a minimum pitch between the patterns implemented by the EUV lithography process of the present embodiment may be about 45 nm or less. That is, by performing the EUV lithography process, elaborate and fine patterns may be formed even without the MPT.

After the patterns are formed on the semiconductor substrate 100, the patterns may be inspected using the pattern defect inspection device 1000 of FIG. 1 (S220). The semiconductor substrate 100, on which the patterns are formed, may be loaded onto the stage 10 of the pattern defect inspection device 1000, and the inspection apparatus 20 of the pattern defect inspection device 1000 may inspect the patterns on the semiconductor substrate 100. The pattern defect inspection device 1000 may be used to measure dimensions of the patterns formed on the semiconductor substrate 100 or to detect defects. The pattern defect inspection device 1000 may inspect the patterns on the semiconductor substrate 100 using the pattern defect inspection method according to the embodiments described above with reference to FIGS. 6 to 9.

It may be determined whether an inspection value according to an inspection result of the pattern defect inspection device 1000 is within an allowable range (S230). If the inspection value is out of the allowable range, an alarm may ring (S240), and if the inspection value is within the allowable range, a subsequent process may be performed on the semiconductor substrate 100. In at least one embodiment, when the inspection result is within an allowable range the processor 30 may initiate the subsequent process automatically (S250). In at least one embodiment, when the inspection value is out of the allowable range, the processor 30 may remove the semiconductor substrate 100 from further processing (e.g., by discarding the semiconductor substrate 100) and/or initiate reprocessing of the semiconductor substrate 100 based on a determination that, e.g., the defects are, e.g., of a correctable type. In at least some embodiments, the processor 30 may initiate a maintenance process for the EUV lithography apparatus and/or for components included therein based on a determination that, e.g., the defects are not within a tolerance value for the EUV lithography apparatus.

According to at least example embodiment of the inventive concepts, the patterns on the semiconductor substrate 100 may be formed by performing a photolithography process using EUV light and may be inspected using the inspection method and system described above with reference to FIGS. 6 to 10. In these cases, the inspection time for the patterns may be shortened, and defects that may occur in the patterns may be easily detected. As a result, defects in a semiconductor device formed using the patterns may be minimized. Consequently, the method of manufacturing a semiconductor device capable of reducing the occurrence of defects may be provided.

While the inventive concepts have been particularly shown and described with reference to embodiments thereof, it will be understood that various changes in form and details may be made therein without departing from the spirit and scope of the following claims.

What is claimed is:

1. A pattern defect inspection device comprising:
an inspection apparatus configured to inspect a pattern on a substrate;
a database storing a pattern layout including a plurality of defect patterns from the inspection apparatus, a field of view (FOV) size, and a target measurement number; and
a processor configured to
set a plurality of inspection regions of the inspection apparatus based on the pattern layout,
search for a region defect pattern existing in at least one of the plurality of inspection regions in the pattern layout using a binary search,
arrange the plurality of inspection regions based on the region defect pattern,
remove at least one overlapping region from the plurality of inspection regions based on the FOV size, and
select an inspection region, other than the at least one overlapping region, from among the plurality of inspection regions, as a final inspection region.

2. The pattern defect inspection device of claim 1, wherein the processor is configured to set a point corresponding to one defect pattern, among the plurality of defect patterns, in the pattern layout as a first point, and to search for a first defect pattern within a range of a first distance in a first direction from the first point.

3. The pattern defect inspection device of claim 2, wherein the processor is configured to search for a second defect pattern existing within a range of a second distance in a second direction from the first point in the pattern layout, and the second direction perpendicular to the first direction.

4. The pattern defect inspection device of claim 3, wherein the processor is configured to set the second defect pattern as a region defect pattern of a first inspection region based on the first point.

5. The pattern defect inspection device of claim 1, wherein the processor is configured to place each of the plurality of inspection regions based on the plurality of defect patterns and to search for the region defect pattern of each of the plurality of inspection regions.

6. The pattern defect inspection device of claim 1, wherein the processor is configured to arrange the plurality of inspection regions in descending order according to a pattern number of the region defect pattern in each of the plurality of inspection regions.

7. The pattern defect inspection device of claim 1, wherein the inspection apparatus is at least one of a scanning electron microscope (SEM), a transmission electron microscope (TEM), or an electron beam inspection apparatus.

8. The pattern defect inspection device of claim 1, wherein
the removing the at least one overlapping region includes determining whether the plurality of inspection regions overlap with a reference region, and
the processor is configured to set the reference region based on an order in which the plurality of inspection regions are arranged.

9. The pattern defect inspection device of claim 8, wherein the processor is configured to perform the removing the at least one overlapping inspection region after the setting the reference region from the plurality of inspection regions.

10. The pattern defect inspection device of claim 8, wherein
the FOV size includes a first horizontal directional length that is a first FOV size in a first direction and a second vertical directional length that is a second FOV size in a second direction perpendicular to the first direction, and
the processor is configured to determine that a determination target region overlaps with the reference region when at least one of a horizontal distance between a first reference point of the reference region and a second reference point of the determination target region, among the plurality of inspection regions, in the first direction is less than the first horizontal directional length or a vertical distance between the first reference point and the second reference point in the second direction is less than the second vertical directional length.

11. The pattern defect inspection device of claim 1, wherein the removing the at least one overlapping region includes determining whether the plurality of inspection regions overlap, and
the processor is configured to stop the determining whether the plurality of inspection regions overlap when a number of inspection regions determined not to overlap reaches the target measurement number.

12. A pattern defect inspection device comprising:
an inspection apparatus configured to inspect a pattern on a substrate;
a database storing a pattern layout including a plurality of defect patterns from the inspection apparatus, a field of view (FOV) size, a target inspection time, and a target measurement number; and
a processor configured to set a plurality of inspection regions of the inspection apparatus based on the pattern layout,
wherein the processor is configured to
measure a number of defect patterns in each of the plurality of inspection regions based on the FOV size,
determine whether the plurality of inspection regions overlap by setting one of the plurality of inspection regions as a reference region, the reference region set based on an order in which the number of defect patterns increases,
remove an overlapping region overlapping the reference region,
select an inspection region from among the plurality of inspection regions, other than the overlapping region which is removed, as a final inspection region, and correct the FOV size and the target measurement number and reselect the plurality of inspection regions when an expected inspection time for the final inspection region exceeds the target inspection time.

13. The pattern defect inspection device of claim 12, wherein,
the processor is configured to transfers the final inspection region to the inspection apparatus when an inspection time for the final inspection region is determined to be equal to or less than the target inspection time, and
the inspection apparatus is configured to inspect the pattern on the substrate corresponding to the final inspection region.

14. The pattern defect inspection device of claim 12, wherein the measuring the number of defect patterns in each of the plurality of inspection regions includes
setting, as a first point, a point corresponding to one of the plurality of defect patterns,
searching for first defect patterns within a range of a first distance in a first direction from the first point,
searching for a second defect pattern, among the first defect patterns, within in a range of a second distance in a second direction perpendicular to the first direction from the first point in the pattern layout in the first defect pattern, and
determining the number of defect patterns based on a number of the second defect patterns.

15. The pattern defect inspection device of claim 14, wherein
the FOV size includes a first horizontal directional length that is an FOV size in the first direction and a second vertical directional length that is an FOV size in the second direction perpendicular to the first direction, and
the first distance corresponds to the first horizontal directional length, and the second distance corresponds to the second vertical directional length.

16. The pattern defect inspection device of claim 12, wherein the processor is configured to
stop the determining whether the plurality of inspection regions overlap when a number of non-overlapping inspection regions determined not to overlap from the plurality of inspection regions reaches the target measurement number, and
select the non-overlapping inspection region as the final inspection region.

17. A pattern defect inspection method comprising:
searching for region defect patterns existing in at least one of a plurality of inspection regions in a pattern layout using a binary search, the patter layout including a plurality of defect patterns;
arranging the plurality of inspection regions in a descending order based on a number of the region defect patterns in the plurality of inspection regions;
removing at least one overlapping region, among the plurality of inspection regions, based on a field of view (FOV) size;
selecting an inspection region, other than the overlapping region, from among the plurality of inspection regions, as a final inspection region; and
inspecting a pattern on a substrate corresponding to the final inspection region.

18. The pattern defect inspection method of claim 17, wherein the searching for the region defect patterns include:
setting, as a first point, a point corresponding to one of the plurality of defect patterns,
searching for a first defect pattern within a range of a first distance in a first direction from the first point,
searching for a second defect pattern, among the first defect patterns, within a range of a second distance in a second direction perpendicular to the first direction from the first point in the pattern layout, and
determine a number of the defect patterns based on a number of second defect patterns, and
wherein the searching for the region defect pattern is repeated for each of the plurality of inspection regions.

19. The pattern defect inspection method of claim 18, wherein the first distance corresponds to a first horizontal directional length, which is an FOV size in the first direction, and the second distance corresponds to a second vertical directional length, which is an FOV size in the second direction perpendicular to the first direction.

20. The pattern defect inspection method of claim 19, wherein the selecting the final inspection region includes
determining whether an expected inspection time for the final inspection region is equal to a target inspection time, and
reselecting the final inspection region changing the size of the plurality of inspection regions and the number of inspection regions when the expected inspection time is greater than the target inspection time.
